(19) United States
(12) Patent Application Publication
(10) Pub. No.: US 2008/0263877 A1
(43) Pub. Date: Oct. 30, 2008

(54) Laser scribing system and method of use

(75) Inventors: Serge Maneuf, Amilly (FR); Roger Desailly, Vitry aux Loges (FR); Robin Swain, Trabuco Canyon, CA (US)

Correspondence Address: NEWPORT CORPORATION, 1791 DEERE AVENUE, IRVINE, CA, 92606, US

(73) Assignee: Newport Corporation, Irvine, CA (US)

(21) Appl. No.: 12/079,232

(22) Filed: Mar. 25, 2008

Related U.S. Application Data
(60) Provisional application No. 60/926,114, filed on Apr. 24, 2007.

(51) Int. Cl. G03F 9/00

(52) U.S. Cl. 33/32.5

(57) ABSTRACT

The present application is directed to a laser scribing system for scribing photovoltaic substrates and includes a support body, one or more positioning devices positioned proximate to the support body and configured to engage and position one or more photovoltaic substrates relative to the support body, at least one grate system positioned proximate to the support body, the grate system formed from one or more grate members, the grate members defining one or more scribing passages in the grate system, and at least one scribe system positioned proximate to the support body, the scribe system having at least one scribe system body disposing one or more scribe devices, the scribe devices positioned proximate to the scribing passages and configured to scribe the substrate supported by the support body.

### CROSS REFERENCE TO RELATED APPLICATIONS

The present application claims priority to U.S. Provisional Patent Application Ser. No. 60/919,570, filed Mar. 23, 2007, and U.S. Provisional Patent Application Ser. No. 60/926,114, filed Apr. 24, 2007, the contents of which are incorporated by reference in their entirety herein.

### BACKGROUND

It is generally accepted within the scientific community that the increased use of fossil fuels has and will continue to lead to global climate change. More specifically, the use of fossil fuels has led to an increase in the amount CO₂ in the atmosphere which may result in an alteration in the natural weather patterns around the world. For example, recent studies have shown decreases in the size of the polar ice caps, which may result in an increase in sea levels and/or a change in the salinity of the oceans, both which may have devastating effects on the ecosystem. Furthermore, increased industrial development and a decreased supply of usable fossil fuels has resulted in a growing demand for the development of a renewable or clean energy sources that do not discharge CO₂.

Presently, a number of alternative energy sources are available. For example, nuclear fission has been used to generate electric power. While nuclear fission offers an unlimited source of power, several shortcomings have been identified. For example, radioactive waste is produced as a result of nuclear fission. The handling, transportation, and storing of radioactive waste materials has proven problematic in the past. As such, a safer, sustainable clean energy source is desired. Of the expected clean energy sources, solar cells (photovoltaic cells or elements) are gathering much attention due to their cleanness, safety, and easy handling.

Photovoltaic cells may be manufactured in a variety of ways. One method requires the deposition of one or more transparent conductive oxides onto a substrate. Thereafter, one or more thin film layers are applied to the substrate. Exemplary additional materials include electrolytes, catalysts layers, protective materials, and the like. At various times during the manufacturing process the various layers formed on the substrate may be scribed to control material thicknesses, define passages and pathways, and maximize photovoltaic conversion efficiency.

Presently, a number of systems configured to scribe photovoltaic panels are available. While these systems have proven somewhat useful, a number of shortcomings have been identified. For example, scribing processes performed by these systems tends to be time consuming. As a result, the manufacturing time of thin film photovoltaic cells tends to be unnecessarily lengthy. Further, in some applications, it is desirable to precisely scribe a maximum number of scribe lines onto the substrate. Misalignment of a single scribe element could render the entire substrate useless. Presently available scribing systems require a lengthy and complicated manual calibration method to align and calibrate the scribing elements prior to initiating substrate processing. In addition, many of the presently available scribing systems require at least a portion of the scribing system to be disassembled during the calibration process, further increasing production delays.

Thus, in light of the foregoing, there is an ongoing need for a laser scribing system capable of quickly and efficiently scribing photovoltaic cells.

### SUMMARY

The present application discloses various embodiments of laser scribing systems configured to scribe various substrates. In one application, the various laser scribing systems described herein are useful in efficiently scribing photovoltaic substrates, although the present systems may be easily adapted for processing any variety of substrates.

In one embodiment, the present application is directed to a laser scribing system for scribing photovoltaic substrates and includes a support body, one or more positioning devices positioned proximate to the support body and configured to engage and position one or more photovoltaic substrates relative to the support body, at least one grate system positioned proximate to the support body, the grate system formed from one or more grate members, the grate members defining one or more scribing passages in the grate system, and at least one scribe system positioned proximate to the support body, the scribe system having at least one scribe system body disposing one or more scribe devices, the scribe devices positioned proximate to the scribing passages and configured to scribe the substrate supported by the support body.

In another embodiment, the present application is directed to a pre-scribing stage for use with a laser scribing system for scribing photovoltaic substrates and includes at least one pre-scribe body, at least one support member positioned proximate to the pre-scribe body and configured to support at least one photovoltaic substrate, at least one movable body positioned proximate to the pre-scribe body and movable with respect thereto, the movable body having one or more engaging device positioned thereon, the engaging device configured to controllably engage and position the photovoltaic substrate relative to the pre-scribe body, and at least one pre-scribe element positioned on the support member and configured to the scribe at least one pre-scribe marks on the substrate.

In another embodiment, the present application is directed to a system for scribing photovoltaic substrates and includes a pre-scribe stage comprising at least one engaging device and at least one scribe element positioned on a movable body configured to move in relation to a support member, the engaging device configured to engage and secure a substrate positioned on the pre-scribe stage, the pre-scribe element configured to apply at least one pre-scribe mark to the substrate, and a scribe stage in communication with the pre-scribe stage and comprising at least one engaging device and at least one scribe element positioned on a movable body configured to move in relation to a support member, the engaging device configured to engage and secure a substrate, the scribe stage configured to receive the substrate from the pre-scribe stage and position the substrate on the support member relative to the pre-scribe mark, the scribe element configured to apply one or more scribe marks thereto using the scribe element.

Other aspects of the embodiments of the laser scribing system for photovoltaic substrates as disclosed herein will become apparent from a consideration of the following detailed description.

### BRIEF DESCRIPTION OF THE DRAWINGS

Various embodiments of a laser scribing system for efficiently processing photovoltaic substrates will be explained in more detail by way of the accompanying drawings, wherein

FIG. 1 shows an elevated perspective view of an embodiment of a laser scribing system having a support body and a grate system positioned proximate thereto;

FIG. 2 shows an elevated exploded view of an embodiment of a laser scribing system having a support body and a grate system positioned proximate thereto;

FIG. 3 shows an planar side view of an embodiment of a laser scribing system having a support body and a grate system positioned proximate thereto;

FIG. 4 shows an elevated perspective view of an embodiment of a laser scribing system having a substrate positioned on the grate system, the grate system capable of controllably moving the substrate along the x-axis, y-axis, and z-axis;

FIG. 5 shows a top view of an embodiment of a laser scribing system having a support body and a grate system positioned proximate thereto and supporting a substrate thereon;

FIG. 6 shows an elevated perspective view of an embodiment of a laser scribing system having a support body and a grate system positioned proximate thereto and supporting a substrate thereon;

FIG. 7 shows an elevated exploded view of an embodiment of a laser scribing system having a support body and a grate system positioned proximate thereto;

FIG. 8 shows an elevated perspective view of an embodiment of a laser scribe device and vacuum device used in laser scribe system;

FIG. 9 shows a top view of an alternate embodiment of a laser scribing system;

FIG. 10 shows a elevated perspective view of scribe elements positioned on a scribe device for use with in a laser scribing system;

FIG. 11 shows a top view of an alternate embodiment of a laser scribing system;

FIG. 12 shows a elevated perspective view of scribe elements positioned on a scribe device for use with in a laser scribing system;

FIG. 13 shows an elevated perspective view of another embodiment of a laser scribing system comprised of a pre-scribe stage and a scribe stage;

FIG. 14 shows a top view of the embodiment of a laser scribing system comprised of a pre-scribe stage and a scribe stage shown in FIG. 13;

FIG. 15 shows an elevated perspective view of an embodiment of a pre-scribe stage of a laser scribing system;

FIG. 16 shows an elevated perspective view of an embodiment of a pre-scribe stage of a laser scribing system wherein at least one engaging device of the pre-scribe stage is engaging a substrate;

FIG. 17 shows an elevated perspective view of an embodiment of a pre-scribe stage of a laser scribing system wherein at least one scribe element of the pre-scribe stage is scribing a substrate;

FIG. 18a shows an elevated perspective view of an embodiment of a pre-scribe stage of a laser scribing system having a engaging device configured to engage an controllably position a substrate;

FIG. 18b shows a perspective view of an embodiment of a pre-scribe stage of a laser scribing system having a engaging device configured to engage an controllably position a substrate;

FIG. 19 shows an elevated perspective view of an embodiment of a pre-scribe stage of a laser scribing system having a engaging device engaging and rotating a substrate;

FIG. 20 shows an elevated perspective view of a pre-scribe stage and scribe stage forming an embodiment of a laser scribing system;

FIG. 21 shows an elevated perspective view of an embodiment of a scribe stage a laser scribing system;

FIG. 22 shows an elevated perspective view of an embodiment of a scribe stage of a laser scribing system having a engaging device engaging a substrate;

FIG. 23 shows an elevated perspective view of an embodiment of a scribe stage of a laser scribing system having a scribe devices scribing a substrate; and

FIG. 24 shows an elevated perspective view of an embodiment of a scribe stage of a laser scribing system having a engaging device engaging and rotating a scribed substrate.

### DETAILED DESCRIPTION

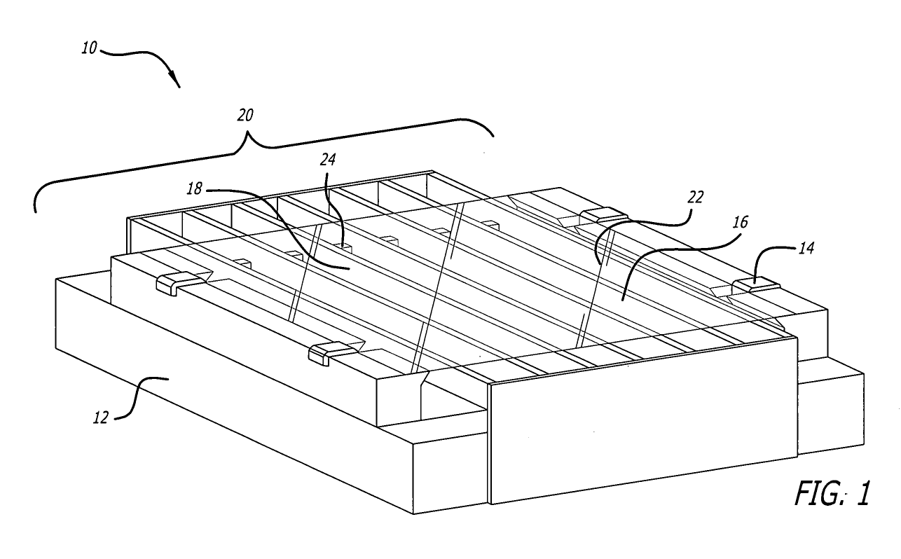

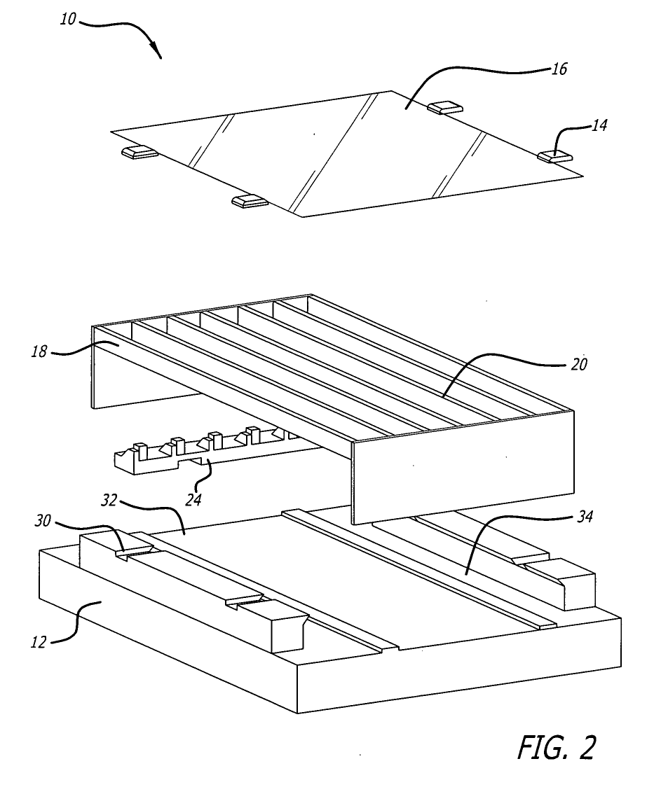

FIGS. 1 and 2 show an embodiment of a laser scribing system. As shown, the laser scribing system 10 includes at least one support body 12 having one or more positioning devices 14 located thereon. In the illustrated embodiment, the laser scribing system 10 includes four positioning devices 14 located on the support body 12. Those skilled in the art will appreciate that any number of positioning devices 14 may be used. Exemplary positioning devices 14 include, without limitation, linear motors, linear actuators, piezo-actuators, air bearing systems, mechanical positioning devices, gantry systems, conveyor belts, roller tracks, air support devices, and the like. The positioning devices 14 may be configured to position one or more substrates 16 relative to the support body 12 or other systems or devices within or positioned proximate to the laser scribing system 10. Exemplary substrates 16 include without limitation, glass substrates, silicon panels or wafers, coated substrates, and the like. In one embodiment, the substrate 16 ranges in size from about 0.5m×0.5m substrate panels to about 6m×6m substrate panels. In another embodiment, the substrate 16 is about 2.6m×about 2.2m substrate panels. Those skilled in the art will appreciate that laser scribing system 10 may be configured to scribe any sized substrates 16.

Referring again to FIGS. 1 and 2, one or more grate members 18 may be positioned proximate to the support body 12. In the illustrated embodiment multiple grate members 18 cooperatively form a grate system 20 having one or more scribing passages 22 formed therein, thereby providing access to the substrate 16 for the scribe system 24. In one embodiment, the grate system 20 is configured to support the substrate 16 positioned proximate thereto. For example, in one embodiment the grate system 20 includes one or more air bearings or air support systems configured to provide support to at least one substrate 16, although those skilled in the art will appreciate that any variety of devices configured to support the substrate 16 may be used with the laser scribing system 10. In an alternate embodiment, the grate system 20 and positioning devices 14 cooperatively support the substrate 16.

FIG. 2 shows an exploded view of an embodiment of a laser scribing system 10. As shown, the support body 12 of the laser scribing system 10 may include one or more positioning device recesses 30 formed thereon and configured to receive at least one positioning device 14 therein. In the illustrated embodiment four positioning device recesses 30 are formed on the support body 12, although those skilled in the art will appreciate that any number of positioning device recesses 30 may be formed thereon. Referring again to FIG. 2, the support body 12 may include at least one movement recess 32 formed therein. In the illustrated embodiment the movement recess 32 includes two rail or gantry devices 34 therein. Optionally, any number of rail devices 34 may be formed within or proximate to the movement recess 32. Further, the rail devices 34 may be parallel, intersecting, constant height, variable height, and the like. In one embodiment the rail devices 34 and scribe system 24 are configured to form in whole or in part at least one linear motor, linear positioning device, air bearing, or other movement system known in the art. Optionally, the rail devices 34 may be configured to permit the movement of the scribe system 24 thereon.

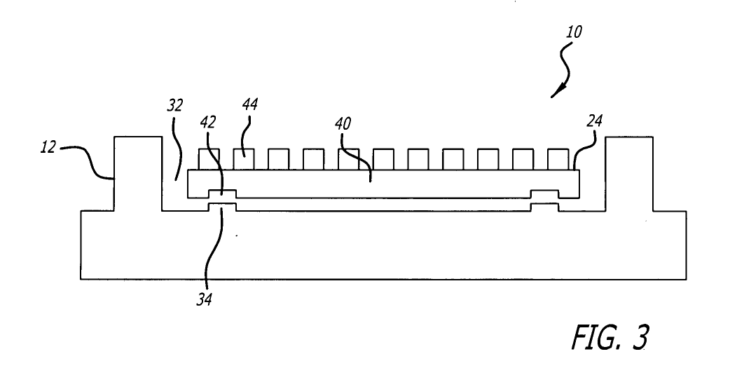

FIG. 3 shows a cross-sectional view of an embodiment of a laser scribing system. As shown, the movement recess 32 formed in the support body 12 of the laser scribing system 10 may be configured to receive at least a portion of the scribe system 24 therein. In the illustrated embodiment, the scribe system 24 includes a scribe system body 40 having one or more rail recesses 42 formed therein. The rail recesses 42 may be sized to receive the rail devices 34 therein. Further, the rail devices 34 and the rail recesses 42 may form in whole or in part at least one linear motor, linear positioning device, air bearing, or other movement system known in the art. Referring again to FIG. 3, at least one scribe system device 44 may be positioned on or otherwise coupled to the scribe system body 40.

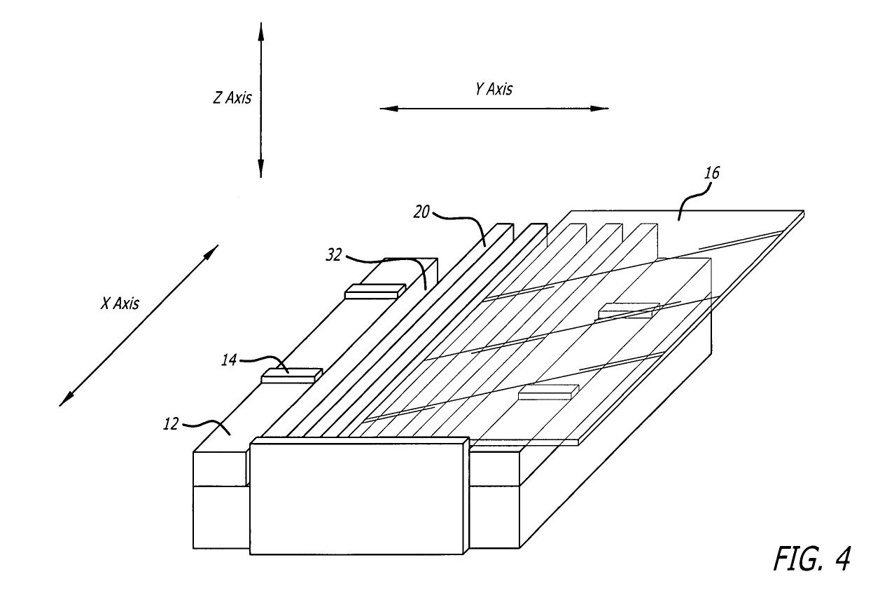

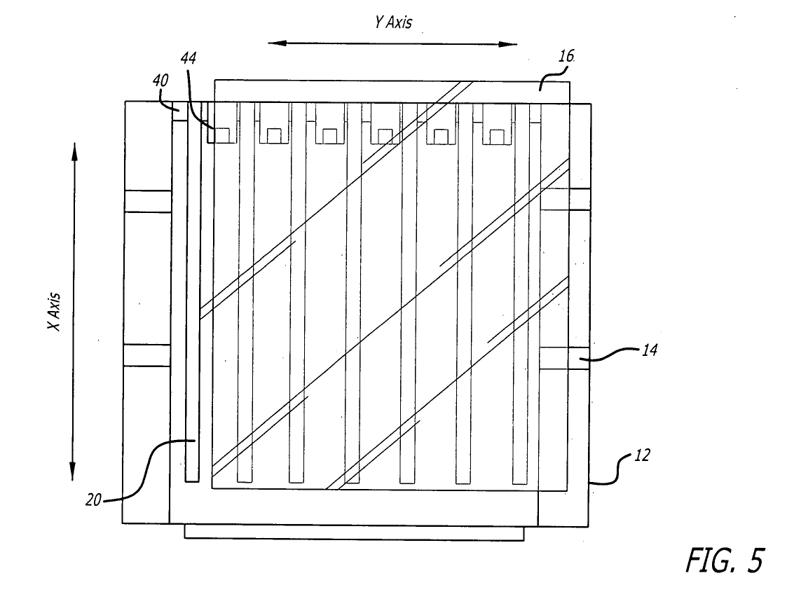

FIGS. 4 and 5 show an embodiment of a laser scribing system during use. As shown, at least a portion of a substrate 16 is positioned on the laser scribing system 10. As stated above, the support body 12, positioning device 14, grate system 20, or any combination thereof may be configured to support the substrate 16. For example, the support body 12, positioning device 14, grate system 20, or any combination thereof may form at least one air bearing or air support system configured to provide support to the substrate 16. For example, as shown in FIGS. 4 and 5, the substrate 16 may be supported by one or more air bearings or air support devices coupled to or otherwise in communication grate device 20 and positioning devices 14 thereby permitting the substrate 16 to be movable along the X axis, Y axis, or both. Further, the scribe system body 40 positioned within the movement recess 32 and having one or more scribing devices 44 positioned thereon may be moveable along the X axis, the Y axis or both. In one embodiment, the substrate 16 is moveable along the Y axis while the scribe system body 40 is moveable along the X axis. Optionally, the scribing system 10 may also be configured to permit the substrate to be adjustably positionable along a Z axis using at least one of the grate system 20, air bearing system, air cushion system, support body 12, or any combination thereof.

Referring again to FIGS. 1-5, any variety of materials may be used to form the laser scribing system 10. For example, the support body 12, grate system 20, and/or scribe system body 40 may be constructed from granite, pourable granite, composite materials, steel, aluminum, polymers, elastomers, ceramic materials, metallic alloys, and the like. Any number and variety of scribing devices 44 may be used with the laser scribing system 10, including, without limitation, diode pumped solid state lasers, fiber lasers, gas lasers, semiconductor lasers, VCSEL lasers, solid state lasers, ultrasonic devices, mechanical scribes, and the like. In one embodiment, the scribing device 44 comprises one or more HIPPO diode-pumped, solid state Q-switched laser manufactured by Spectra-Physics, Inc. and configured to output a laser signal having a wavelength from about 400 nm to about 200 nm. For example, in one embodiment the HIPPO scribing device 44 is configured to output a laser signal having a wavelength of about 1064 nm. In an alternate embodiment, the HIPPO scribing device 44 is configured to output a frequency doubled laser signal having a wavelength of about 532 nm. The laser scribe device 44 may or may not provide a pulsed output.

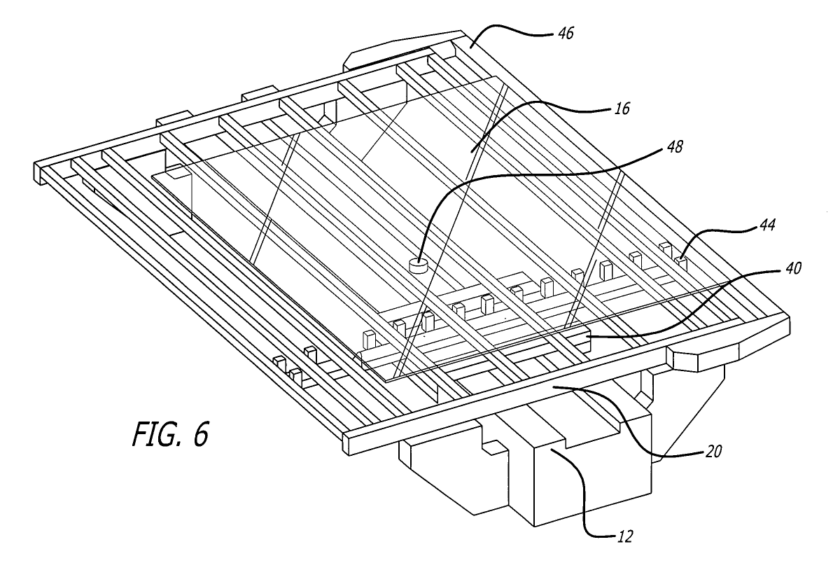

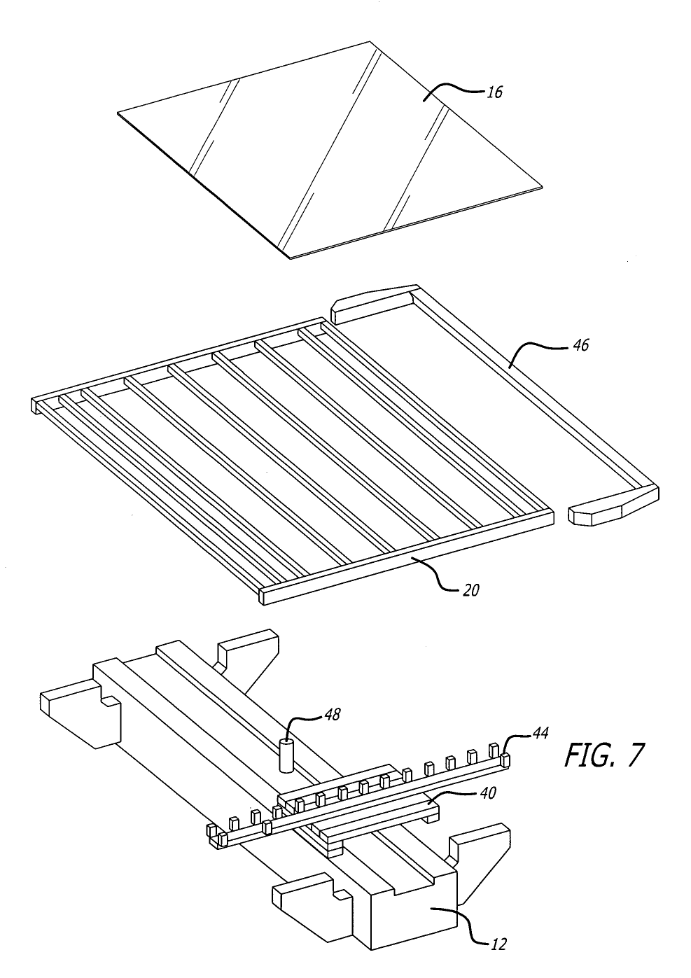

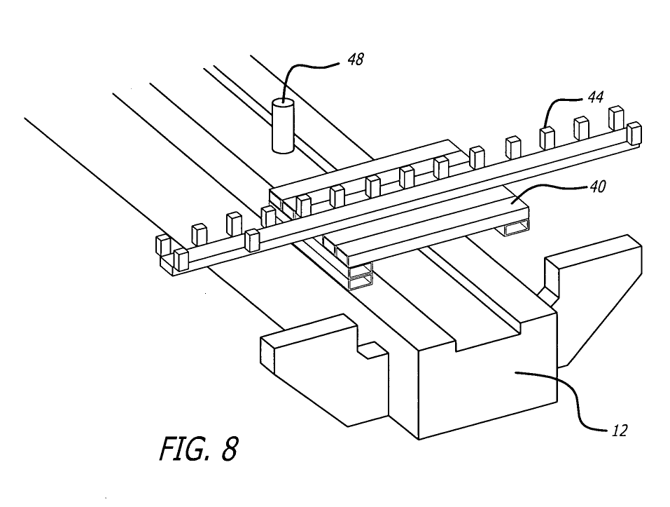

Optionally, the scribing system 10 shown in FIGS. 1-5 may include one or more additional positioning devices or devices configured to position and secure the substrate 16 of the support body 12. For example, FIGS. 6-8 shows an embodiment of a scribing system 10 having at least one substrate positioning device 46 coupled to or otherwise in functional communication with the support body 12, the grate system 20, or both. The substrate positioning device 46 may comprise a linear motor, linear drive, mechanical drive, air bearing system, air cushion system, piezo-motor(s) and the like. Further, the substrate positioning device 46, the grate system 20, or the various components thereof, including any associated air bearing systems and positioning members may be configured to permit the rotation of the substrate 16 around any point thereon.

Referring again to FIGS. 6-8, one or more additional positioning devices or securing devices may be used with the scribing system 10. For example, one or more vacuum or substrate stabilizing devices 48 may be positioned on the support body, 12, grate system 20, and/or the substrate positioning device 46. The vacuum device 48 may be configured to secure the substrate 16 during processing. Further, the vacuum device 48 may be used to assist in the rotation or movement of the substrate before, during, or following laser processing.

Optionally, the laser scribing system 10 may include a variety of other devices commonly used in the manufacture of photovoltaic devices, semiconductor devices, or both. For example, the laser scribing system 10 may be computer controlled. As such, one or more computers, controllers, and/or processors may be coupled to or otherwise in communication with the laser scribing system 10. Further, one or more cameras, metrology devices or systems, galvo systems, inspection devices, registration devices, bar code readers, bar code writers, fiducial rendering/reading devices may be include in the system or coupled thereto.

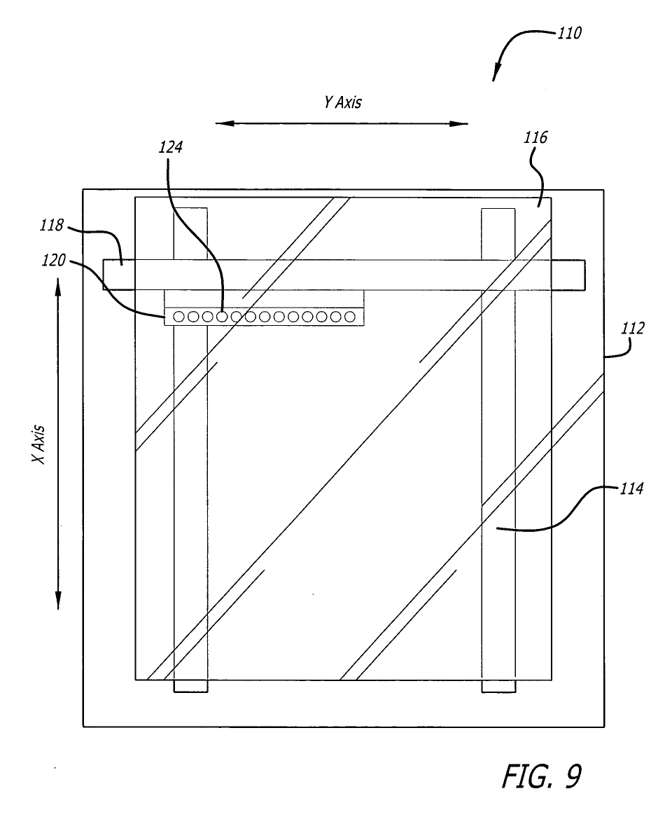

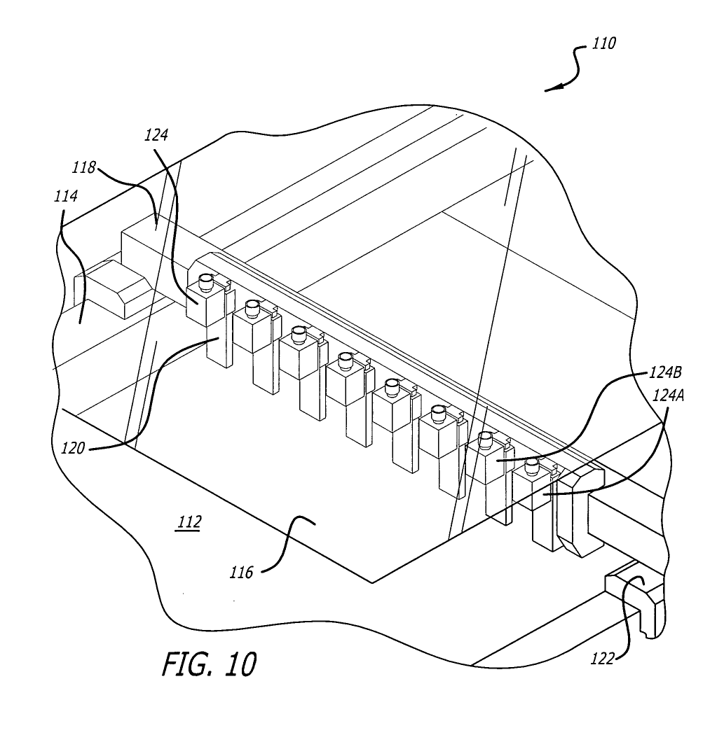

FIGS. 9-10 show an alternate embodiment of a scribing system. As shown, the scribing system 110 includes at least one support body 112 having at least one rail or gantry device 114 formed thereon or otherwise coupled thereto. The support body 112, the rail device 114, or both may be configured to support at least one substrate 116. Like the previous embodiment, the support body 112, the rail device 114, or both may form an air bearing, air support, or other system configured to support the substrate 116. At least one scribe device support 118 configured to support one or more scribing devices 120 may be positioned on or otherwise functionally coupled to at least one of the support body 112 or the rail device 114. The scribing device 120 includes one or more scribing elements 124 thereon. As shown in FIG. 10, the scribe device support 118 may be coupled to the rail device 114 with one or more movement devices 122. For example, the movement device 122 and rail device 114 may cooperatively form a linear motor or liner movement system. Further, the scribe device 120 and scribe device support 118 may also form a linear motor or linear movement system. As such, the movement system formed by the movement device 122 and rail device 114 may cooperatively enable movement of the scribe device support 118 along the X axis. Similarly, the movement system formed by scribe device 120 and scribe device support 118 may cooperatively enable movement of the scribe device support 120 along the Y axis.

FIG. 10 shows a detailed view of an embodiment of scribing elements 124 positioned on the scribe device 120 coupled to the scribe device support 118. In one embodiment, at least one scribe element 124 is movably coupled to the scribe device 120 which is affixed to the scribe device support 118. For example, the scribe element 124a may be configured to be controllably positionable with respect to another scribe element 124b positioned on the scribe device 120. More specifically, a first scribe element 124a may be configured to be adjustable along at least one of the x-axis, y-axis, and z-axis of at least one other scribe element 124. As such, the scribe device 120 and/or scribe elements 124 may include any number and variety of positioning devices thereon, including, without limitation, linear motors, linear drives, mechanical drives, air bearing systems, air cushion systems, piezo-actuators, piezo-motors, stepper motors, mechanical positioners, worm drives, and the like. Further, at least one controller and/or detector may be coupled to at least one positioner coupled to at least one scribe element 124. For example, a processor and detector may be coupled to at least one scribe element 124 and configured to permit the detection of at least one scribe line formed on the substrate 116 and automatically reposition the scribe element 124, thereby permitting the automated calibration of the scribing system 110. Optionally, the adjustment of at least one scribing element 124 may be accomplished manually. Those skilled in the art will appreciate that the various embodiments of scribing systems disclosed herein may include manually adjustable or automatically adjustable scribe elements.

Like the previous embodiment, any variety of materials may be used to form the laser scribing system 110. For example, the support body 112, the rail device 114, and/or the scribe device support 118 may be constructed from granite, pour granite, composite materials, steel, aluminum, polymers, elastomers, ceramic materials, metallic alloys, and the like. Any number and variety of scribing elements 124 may be used with the laser scribing system 110, including, without limitation, diode pumped solid state lasers, fiber lasers, gas lasers, semiconductor lasers, VCSEL lasers, solid state lasers, ultrasonic devices, mechanical scribes, and the like. In one embodiment, the scribing element 124 comprises one or more HIPPO diode-pumped, solid state Q-switched laser manufactured by Spectra-Physics, Inc. and configured to output a laser signal having a wavelength from about 400 nm to about 200 nm. For example, in one embodiment the HIPPO scribing element 124 is configured to output a laser signal having a wavelength of about 1064 nm. In an alternate embodiment, the HIPPO scribing element 124 is configured to output a frequency doubled laser signal having a wavelength of about 532 nm As such, the scribing elements 124 may or may not provide a pulsed output.

Optionally, the laser scribing system 110 may include a variety of other devices commonly used in the manufacture of photovoltaic devices, semiconductor devices, or both. For example, the laser scribing system 110 may be computer controlled. As such, one or more computers, controllers, and/or processors may be coupled to or otherwise in communication with the laser scribing system 110. Further, one or more cameras, metrology devices or systems, galvo systems, inspection devices, registration devices, bar code readers, bar code writers, fiducial rendering/reading devices may be include in the system or coupled thereto.

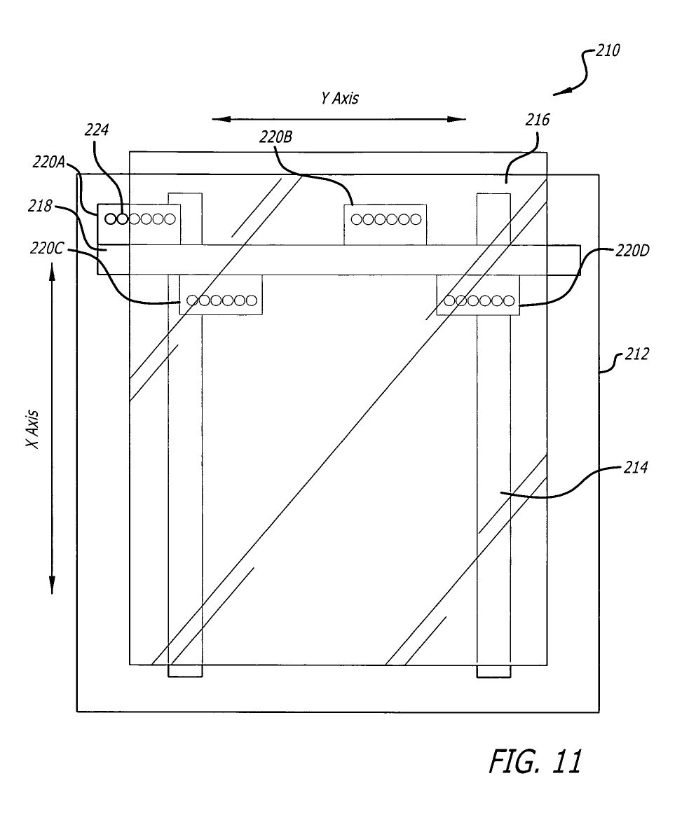

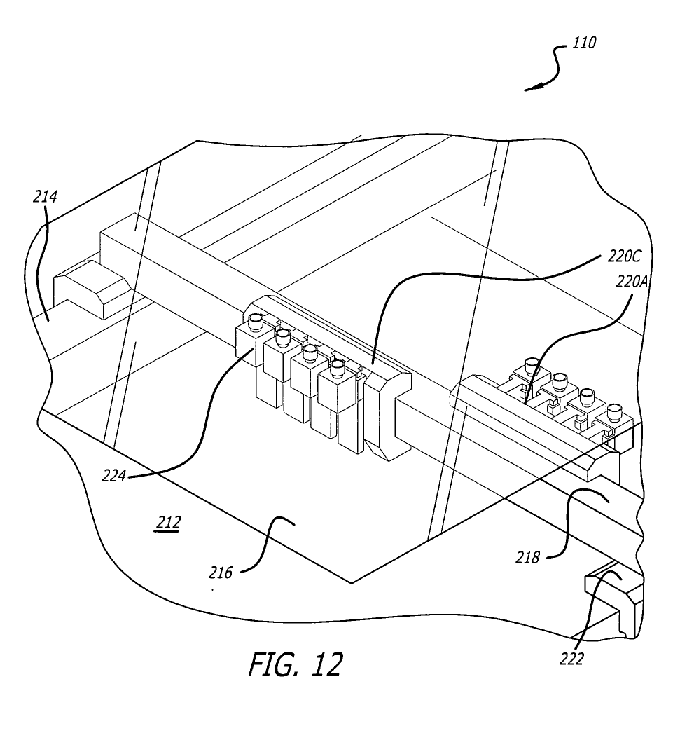

FIGS. 11-12 show an alternate embodiment of a scribing system. As shown, the scribing system 210 includes a support body 212 having at least one rail or gantry device 214 formed thereon or otherwise coupled thereto. The support body 212, the rail device 214, or both may be configured to support a substrate 216. Like the previous embodiment, the support body 212, the rail device 214, or both may form an air bearing, air support, or other system configured to support the substrate 216. At least one scribe device support 218 configured to support one or more scribing devices 220 may be positioned on or otherwise functionally coupled to at least one of the support body 212 or the rail device 214. In the embodiment illustrated in FIGS. 11 and 12, scribing devices 220A and 220B are opposing scribing devices 220C and 220D, all of which are coupled to the scribing device support 218. Optionally, scribing devices 220A, 220B, 220C, and 220D may be configured to operate independently, in concert, or in any combination thereof. For example, scribing devices 220A and 220B may be configured to operate in concert. Similarly, scribing devices 220C and 220D may be configured to operate in concert. The scribing device 220 includes one or more scribing elements 224 thereon. As shown in FIG. 11, the scribe device support 218 may be coupled to the rail device 214 with one or more movement devices 222. For example, the movement device 222 and rail device 214 may cooperatively form a linear motor or liner movement system. Further, the scribe devices 220A-220D and scribe device support 218 may also form a linear motor or linear movement system. As such, the movement system formed by the movement device 222 and rail device 214 may cooperatively enable movement of the scribe device support 218 along the X axis. Similarly, the movement system formed by scribe devices 220A-220D and scribe device support 218 may cooperatively enable movement of the scribe devices 220A-220D along the Y axis.

Like the previous embodiment, any variety of materials may be used to form the laser scribing system 210. For example, the support body 212, the rail device 214, and/or the scribe device support 218 may be constructed from granite, pour granite, composite materials, steel, aluminum, polymers, elastomers, ceramic materials, metallic alloys, and the like. Any number and variety of scribing elements 224 may be used with the laser scribing system 110, including, without limitation, diode pumped solid state lasers, fiber lasers, gas lasers, semiconductor lasers, VCSEL lasers, solid state lasers, ultrasonic devices, mechanical scribes, and the like. In one embodiment, the scribing element 224 comprises one or more HIPPO diode-pumped, solid state Q-switched laser manufactured by Spectra-Physics, Inc. and configured to output a laser signal having a wavelength from about 400 nm to about 200 nm. For example, in one embodiment the HIPPO scribing element 224 is configured to output a laser signal having a wavelength of about 1064 nm. In an alternate embodiment, the HIPPO scribing element 224 is configured to output a frequency doubled laser signal having a wavelength of about 532 nm As such, the scribing elements 224 may or may not provide a pulsed output.

Optionally, the laser scribing system 210 may include a variety of other devices commonly used in the manufacture of photovoltaic devices, semiconductor devices, or both. For example, the laser scribing system 210 may be computer controlled. As such, one or more computers, controllers, and/or processors may be coupled to or otherwise in communication with the laser scribing system 210. Further, one or more cameras, metrology devices or systems, galvo systems, inspection devices, registration devices, bar code readers, bar code writers, fiducial rendering/reading devices may be include in the system or coupled thereto.

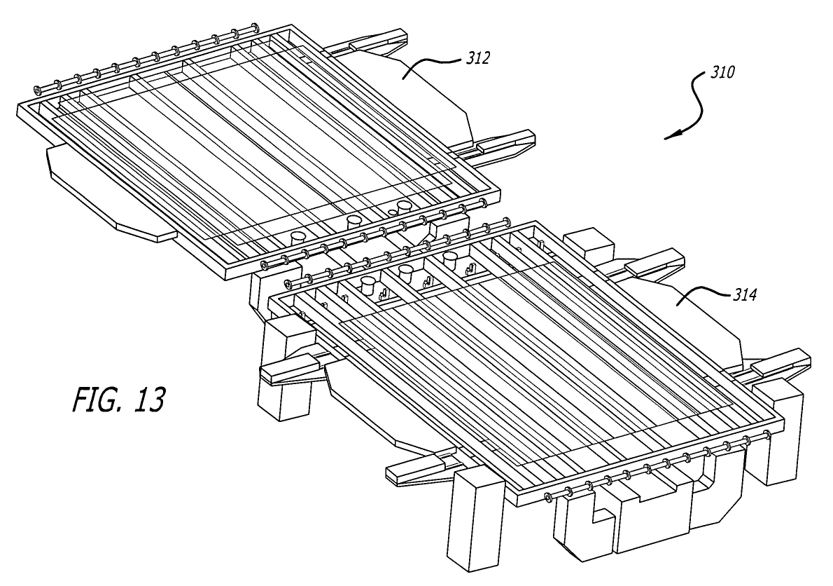

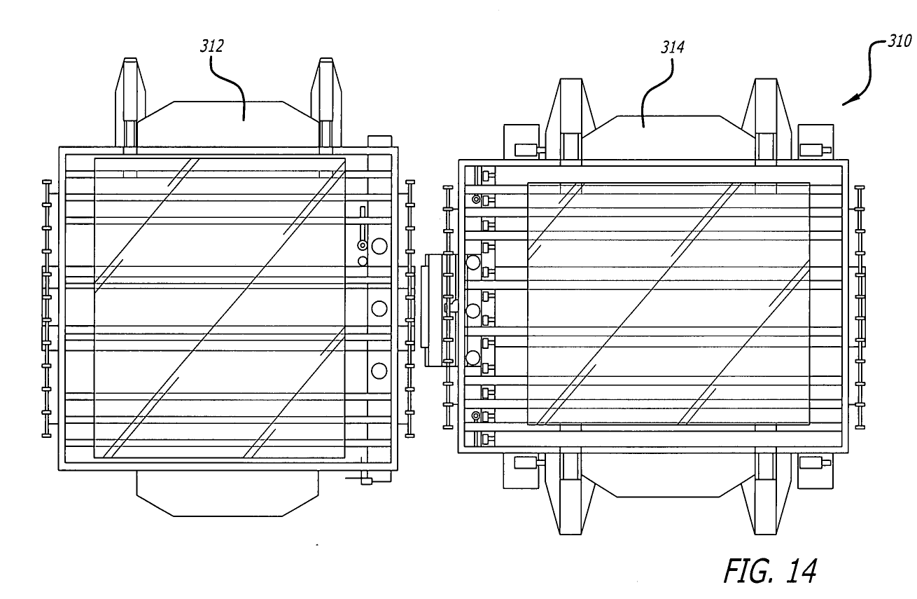

FIGS. 13 and 14 show another embodiment of a laser scribing system. As shown, the laser scribing system 310 includes at least one pre-scribe stage 312 and at least one scribe stage 314. In the illustrated embodiment the pre-scribe stage 312 is positioned proximate to the scribe stage 314. Optionally, the pre-scribe stage 312 need not be positioned proximate to the scribe stage 314.

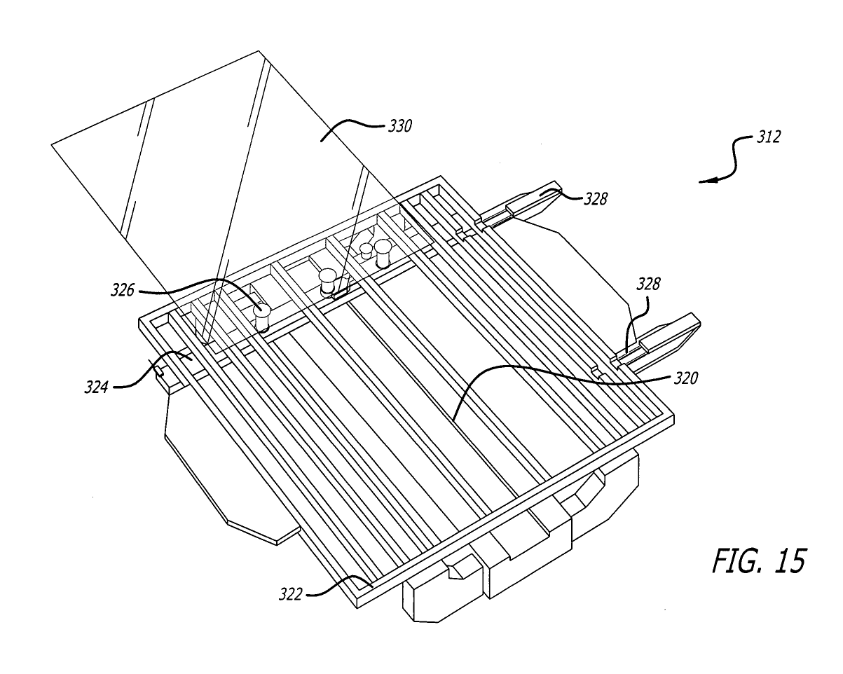

FIGS. 15-18b show various views of an embodiment of a pre-scribe stage 312 of the laser scribing system 310 shown in FIGS. 13- and 14 during use. As shown, the pre-scribing stage 312 includes a pre-scribe body 320 having a support body 322 positioned proximate thereto. In one embodiment, the pre-scribe body is manufactured from a composite moldable granite material, although those skilled in the art will appreciate that the pre-scribe body 320 may be manufactured from any variety of materials. Exemplary materials include, without limitation, granite, marble, stone, composite materials, polymers, steel, lead, aluminum, and the like. In the illustrated embodiment, the support member 322 is coupled to the pre-scribe body 320. Optionally, the support member 322 may be positioned proximate to the pre-scribe body 320. In one embodiment, the support member 322 comprises an air-cushion or air-support device configured to support a substrate 330 on a volume of air or other gas. In an alternate embodiment, the support member 322 comprises a conveyer support device having one or more support devices thereon. Exemplary support devices include, without limitation, bearings, wheels, rollers, belts, and the like.

Referring again to FIGS. 15-18b, the pre-scribe stage 312 further includes at least one movable body 324 configured to be movable with respect to at least one of the pre-scribe body 320 and the support member 322. In one embodiment, the movable body 324 comprises a linear motor. Optionally, any variety of devices may be used to from the movable body 324 including, without limitation, roller bodies, bearing devise, and the like. One or more engaging devices 326 may be positioned on or otherwise coupled to the movable body 324. In the illustrated embodiment the engaging devices comprise suction cup devices configured to controllable engage and disengage the substrate 330 positioned on or proximate to the support member 322. As such, the engaging devices 326 may be in communication with one or more suction sources. In an alternate embodiment, the engaging devices comprise at least one friction members, silicon devices, elastomer devices, force members, and the like configured to controllably engage and disengage the substrate 330.

Referring again to FIGS. 15-18b, the pre-scribe stage 312 may include one or more stabilizing members 328 configured to controllably engage and disengage the substrate 330. Optionally, the stabilizing members 328 may be also used to controllably position the substrate 330 relative to at least one of the support member 322, movable body 324, engaging devices 326, and the like. In one embodiment, the stabilizing members 328 are configured to engage one surface of the substrate 330. In an alternate embodiment, the stabilizing members 328 are configured to engage multiple surfaces of the substrate 330.

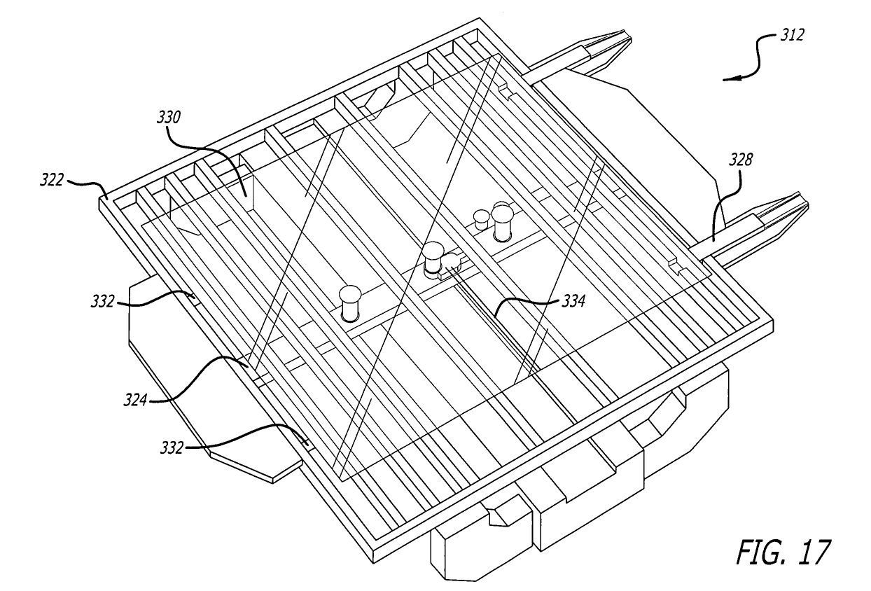

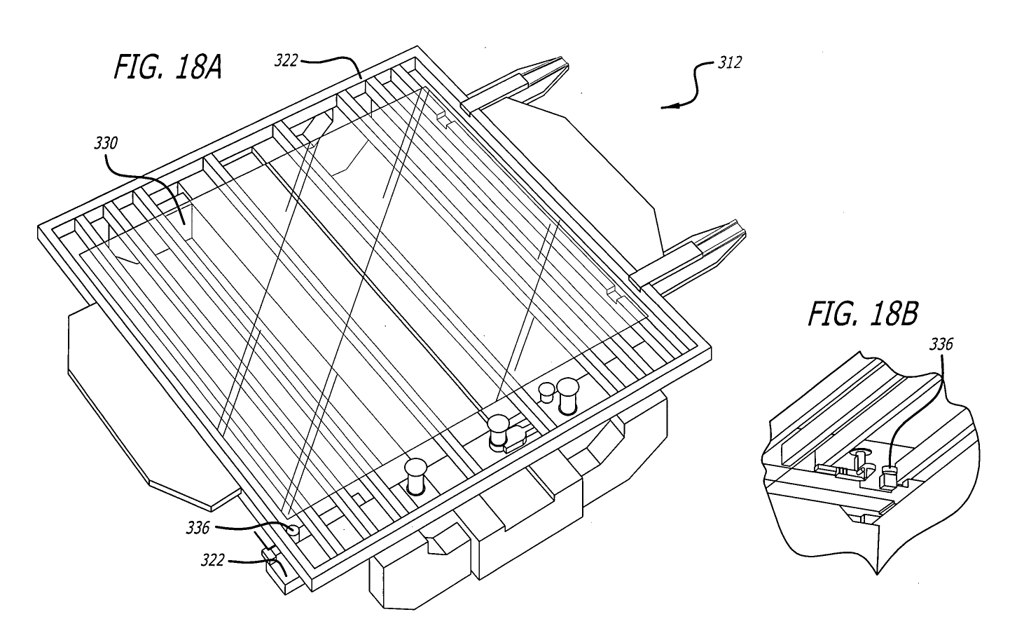

As shown in FIG. 17, the pre-scribe stage 312 may include one or more datums 332 configured to assist in positioning the substrate 330 on the pre-scribe stage 312. Further, as shown in FIGS. 18a and 18b, one or more pre-scribe elements 336 may be positioned on at least one of the support member 322, movable body 324, engaging devices 326, and the like. Exemplary pre-scribing elements 336 include, without limitation, lasers, galvos, mirrors, fast-steering mirrors, gratings, prisms, cameras, detectors, registers, and the like. As shown in FIG. 17, during use the pre-scribing elements 336 are configured to scribe any variety of fiducials, registers, bar codes, serial numbers, part numbers, positioning marks and/or lines, and similar marks 334 on the substrate 330.

Optionally, the pre-scribe stage 312 may be configured to rotate the substrate 330 about any point located on the substrate 330. For example, in the illustrated embodiment a central engaging device 326 is configured to engage and detachably secure the substrate 330. For example, the central engaging device 326 may be configured to secure the substrate 330 using suction and rotate the substrate any number of degree ranging from 1 degree to 360 degrees. In one embodiment, the engaging device 326 may be configured to engage the substrate 330 and rotate the substrate approximately 90 degrees. As such, at least one engaging device 326 may be configured to rotate while engaging the substrate 330.

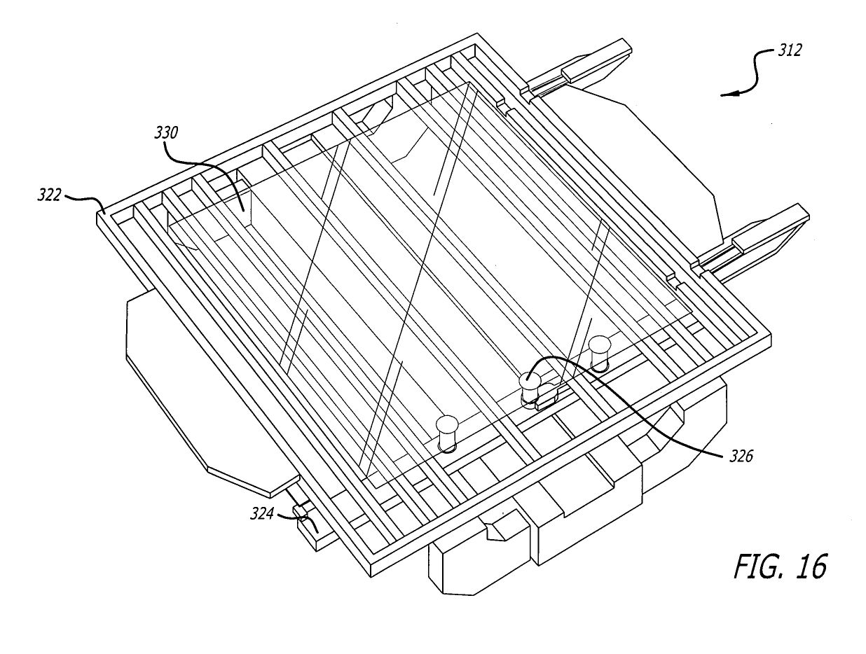

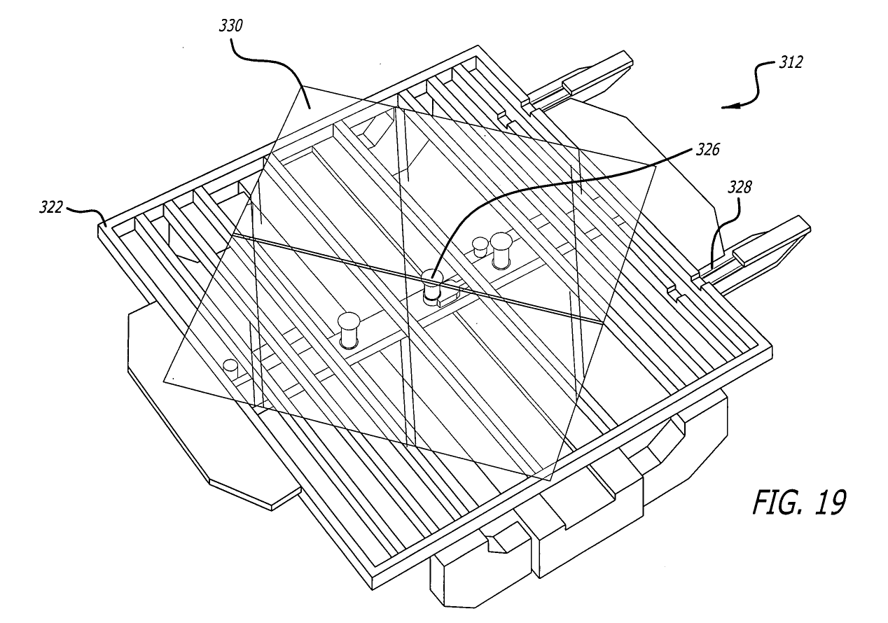

FIGS. 15-19 show an embodiment of a pre-scribe stage 312 of a scribing system 310 during use. As shown in FIG. 15, a substrate 330 is advanced onto the pre-scribe stage 312 such that at least one engaging device 326 located on the movable body 324 may engage and secure the substrate 330. As shown in FIGS. 15 and 16, the movable body 324 pulls the substrate 330 onto the support member 322. As stated above, the support member 322 may comprise an air-support device thereby permitting the substrate 330 to ride along an air cushion. Once positioned on the support member 324, the stabilizers 328 and/or datums 332 secure and position the substrate 330 for the pre-scribing process. As shown in FIGS. 17, 18a, and 18b the scribing elements 336 positioned on the movable body 324 may scribe one or more fiducials or other marks 334 onto the substrate 330. Optionally, as shown in FIG. 19, before, during, or following the pre-scribing process the substrate 330 may be rotated about any point thereon. Thereafter, the pre-scribed substrate 330 may be advanced to the scribe stage 314. (See FIG. 13).

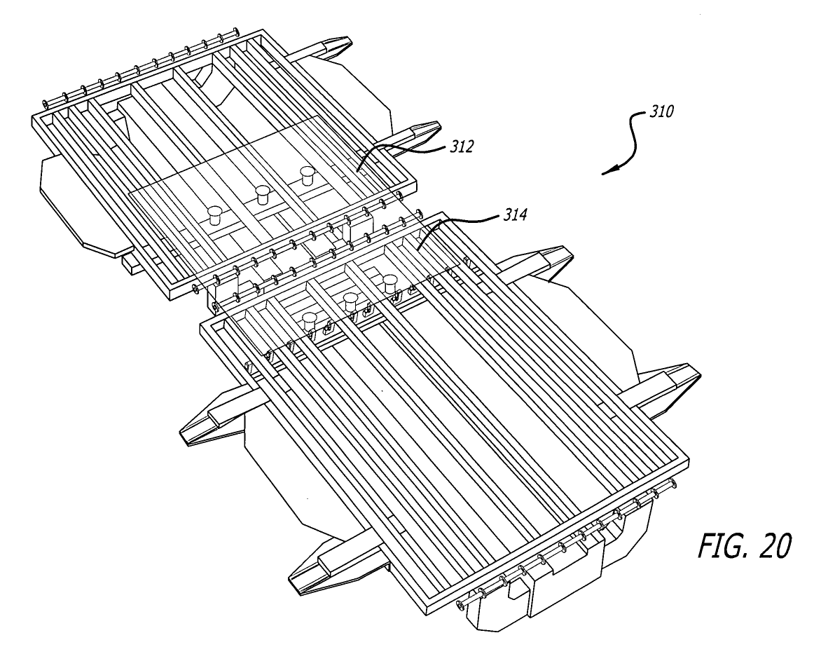

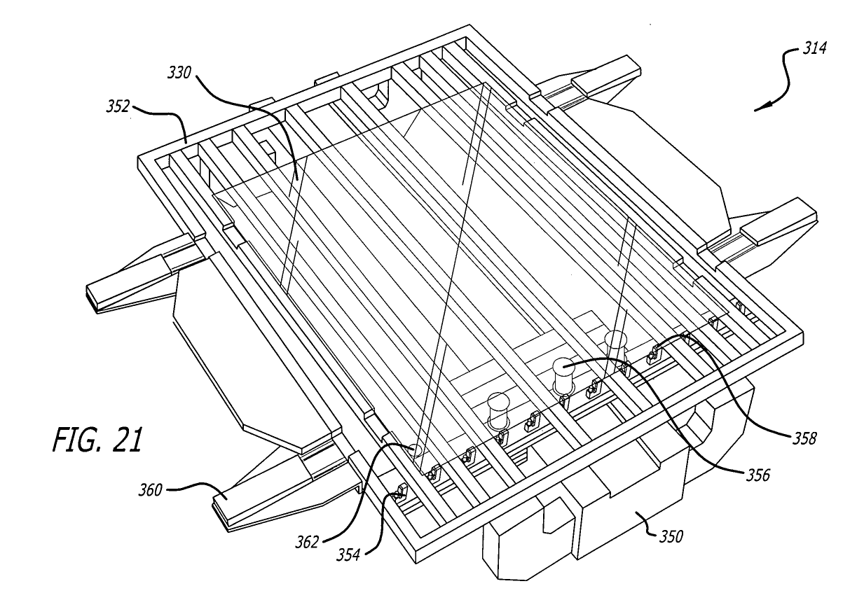

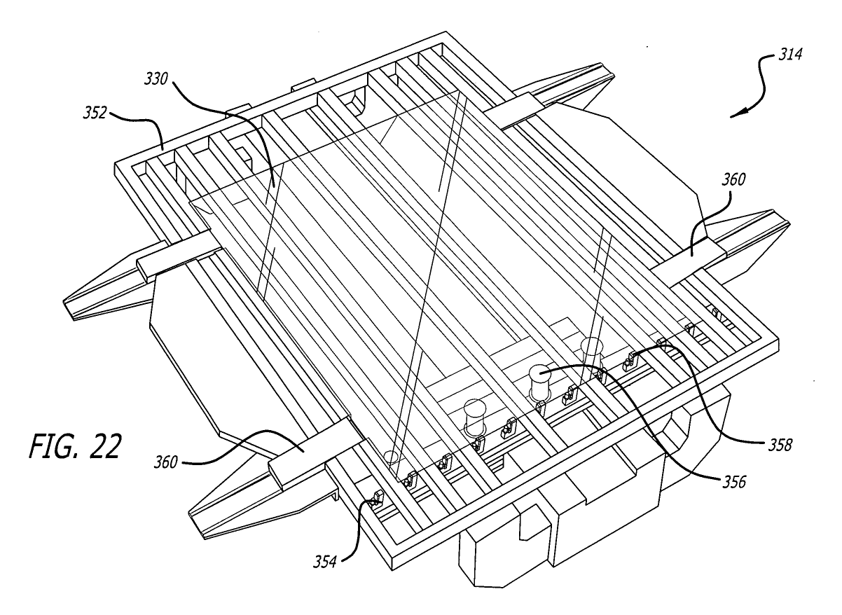

As shown in FIGS. 20-24, following the pre-scribe process, the substrate 330 may be advanced to the scribe stage 314. As stated above, in the illustrated embodiment the pre-scribe stage 312 is positioned proximate to the scribe stage 314, although those skilled in the art will appreciate that the pre-scribe stage 312 need not be positioned proximate to the scribe stage 314. As shown in FIGS. 20 and 21, the engaging devices 326 positioned on the movable body 324 of the pre-scribe stage 312 may engage the substrate 330 and advance at least a portion thereof to the scribe stage 314 such that the engaging devices 356 located on the movable body 354 of the scribe stage 314 can engage and secure the substrate 330. Like the pre-scribe stage 312, at least one engaging device 356 may be configured to be controllably rotatable. Exemplary engaging devices 356 include, without limitations, suction devices, friction members, silicon devices, elastomer devices, force members, and the like configured to controllably engage and disengage the substrate 330.

Thereafter, like the pre-scribe stage 314, at least one movable body 354 may be configured to pull the substrate 330 onto at least one support member 352 of the scribe stage 314. In one embodiment, the support body 352 comprises an air-cushioning or sir-support device, although those skilled in the art will appreciate that any variety of support devices may be used herewith. The support member 352 is positioned on or otherwise coupled to at least one scribe body 350. Like the pre-scribe body 320, the scribe body 350 may be manufactured from any variety of materials, including, without limitation, granite, marble, stone, composite materials, polymers, steel, lead, aluminum, and the like.

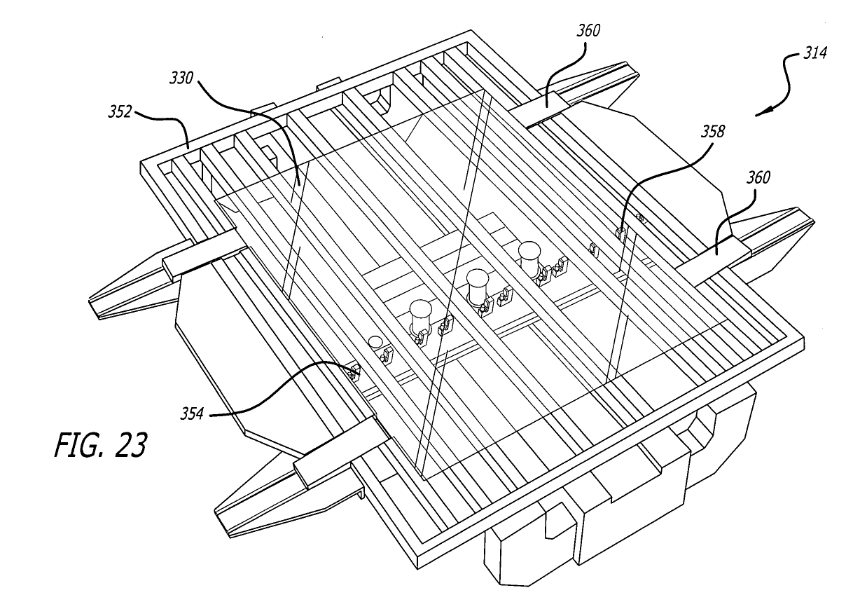

Referring again to FIGS. 20 and 23, the scribe stage 314 includes at least one scribing device 358 positioned on the moveable body 354. In one embodiment, the scribing device 358 comprises one or more laser systems or devices. In the alternative, the scribing device 358 includes at least one laser, mirror, lens, telescope, light source, mechanical scribing device, diamond tool, carbide tool, and the like. Further, the scribe stage 314 includes one or more stabilizing members 360 positioned proximate to the substrate 360. The stabilizing members 360 may be configured to controllably engage, position, and release the substrate 330. For example, the stabilizing members 360 may comprise linear motors and the like. Further, one or more detectors, visualization devices, cameras, and the like may be positioned on the scribe device 314. For example, in the illustrated embodiment at least one camera device 362 is positioned on the movable body 354 and configured to read or identity at least one pre-scribe fiducial 334 (See FIG. 17) formed on the substrate 330.

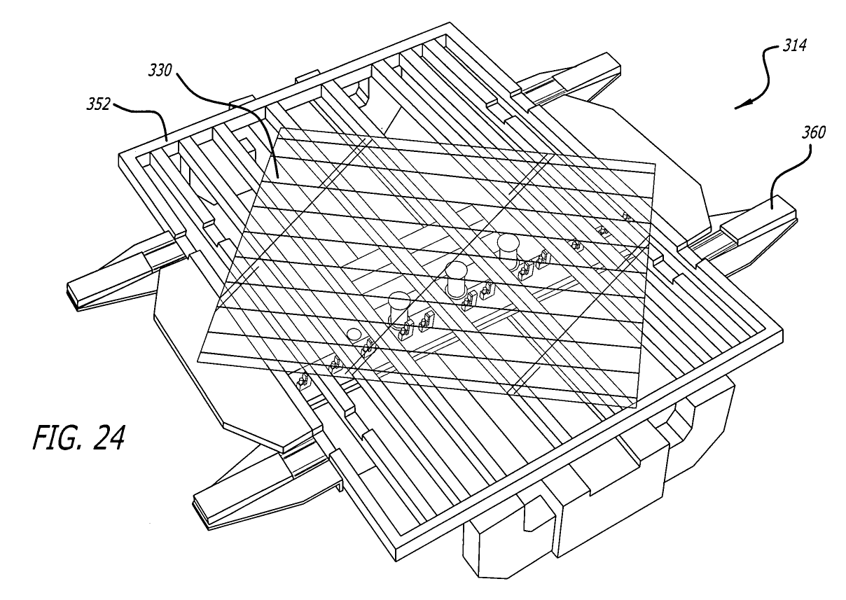

Once the substrate 330 is positioned on the support member 354, the stabilizers 360 engage at least one surface of the substrate 330, thereby securing the substrate 330. In addition, the stabilizers 360 may be configured to position the substrate 330 relative to the support member 352, the movable body 354, the scriber 358, and or the camera 362. Once positioned and secured the scribers 358 and movable body 354 may be actuated to scribe the substrate 330 as desired. Further, the substrate 330 may be rotated before, during, or after the scribing process has commenced as desired. For example, FIG. 24 shows at least one positioning device 356 engaging the substrate 330 and controllably rotating the substrate 330 any number of degrees with respect to the scribe stage 314. In one embodiment, one or more detectors, camera, processors, and the like coupled to the scribe stage 314 may be configured to measure one or more characteristics of at least one scribe line formed on the substrate 330 and adjust one or more elements of the scribe stage 314 accordingly. For example, the spacing of two or more scribe lines formed on the substrate 330 may be measured and one or more scribers 358 may be repositioned accordingly. In one embodiment, the repositioning of the scriber 358 may be automated, thereby permitting automated calibration of the scribe stage 314. Optionally, the scriber 358 may be repositioned manually. In another embodiment, the depth of the scribe line may be measured and adjusted accordingly using various methods known in the art.

The various embodiments disclosed herein are illustrative of the principles of the invention. Other modifications may be employed which are within the scope of the invention. Accordingly, the devices disclosed in the present application are not limited to that precisely as shown and described herein.

What is claimed is:

1. A system for scribing photovoltaic substrates, comprising:
a support body;
one or more positioning devices positioned proximate to the support body and configured to engage and position one or more photovoltaic substrates relative to the support body;
at least one grate system positioned proximate to the support body, the grate system formed from one or more grate members, the grate members defining one or more scribing passages in the grate system; and
at least one scribe system positioned proximate to the support body, the scribe system having at least one scribe system body disposing one or more scribe devices, the scribe devices positioned proximate to the scribing passages and configured to scribe the substrate supported by the support body.

2. The device of claim 1 further comprising:
at least one rail device formed on the support body; and
at least one rail recess formed on the scribe body and configured to receive at least a portion of the rail device therein.

3. The device of claim 1 wherein at least one positioning device comprises a linear motor.

4. The device of claim 1 wherein at least one positioning device comprises at least one positioning device comprises an air bearing system.

5. The device of claim 1 wherein at least one positioning device is selected from the group consisting of linear actuators, piezo-actuators, mechanical positioning systems, gantry devices, belt devices, roller track systems, and air support devices.

6. The device of claim 1 wherein the substrate comprises silica substrates.

7. The device of claim 1 wherein the positioning devices enable the substrate to move along the x-axis relative to the support body.

8. The device of claim 1 wherein the positioning devices enable the substrate to move along the y-axis relative to the support body.

9. The device of claim 1 wherein the positioning devices enable the substrate to move along the z-axis relative to the support body.

10. The device of claim 1 wherein the positioning devices enable the substrate to move along at least one of the x-axis, y-axis, and z-axis relative to the support body.

11. The device of claim 1 wherein the scribe device comprises a diode-pumped, solid-state Q-switched laser configured to emit one or more light beams to the substrate.

12. The device of claim 1 wherein the scribe device is selected from the group consisted of diode-pumped solid state lasers, fiber lasers, gas laser, semiconductor lasers, VCSEL lasers, solid state lasers, ultrasonic devices, and mechanical scribe devices.

13. The device of claim 1 further comprising at least one substrate stabilizing device positioned proximate to the support body, the stabilizing device configured to stabilize the substrate during processing.

14. The device of claim 13 wherein the stabilizing device is configured to assist the positioning device in moving the substrate before and after processing.

15. The device of claim 1 further comprising at least one controller in communication with the scribing system and configured to control and monitor the movement and scribing of the substrate.

16. The system of claim 15 wherein the controller comprises at least one device selected from the group consisting of a processor, computer, camera, metrology device, galvo system, inspection device, registration device, bar code reader, bar code writer, fiducial rending device, and fiducial reading device.

17. A pre-scribing stage for use with a laser scribing system for scribing photovoltaic substrates, comprising:
at least one pre-scribe body;
at least one support member positioned proximate to the pre-scribe body and configured to support at least one photovoltaic substrate;
at least one movable body positioned proximate to the pre-scribe body and movable with respect thereto, the movable body having one or more engaging device positioned thereon, the engaging device configured to controllably engage and position the photovoltaic substrate relative to the pre-scribe body; and
at least one pre-scribe element positioned on the support member and configured to the scribe at least one pre-scribe marks on the substrate.

18. The device of claim 17 wherein the engaging device is configured to rotate the substrate between 1 degree and 360 degrees relative to the support member.

19. The device of claim 17 wherein the pre-scribe element is selected from the group consisting of lasers, galvos, mirrors, fast-steering mirrors, gratings, prisms, cameras, detectors, and registers.

20. The device of claim 17 wherein the pre-scribe mark comprises at least one mark selected from group consisting of fiducials, registers, bar codes, serial numbers, part numbers, positioning marks, and positioning lines.

21. A system for scribing photovoltaic substrates, comprising:
a pre-scribe stage comprising at least one engaging device and at least one scribe element positioned on a movable body configured to move in relation to a support member, the engaging device configured to engage and secure a substrate positioned on the pre-scribe stage, the pre-scribe element configured to apply at least one pre-scribe mark to the substrate; and
a scribe stage in communication with the pre-scribe stage and comprising at least one engaging device and at least one scribe element positioned on a movable body configured to move in relation to a support member, the engaging device configured to engage and secure a substrate, the scribe stage configured to receive the substrate from the pre-scribe stage and position the substrate on the support member relative to the pre-scribe mark, the scribe element configured to apply one or more scribe marks thereto using the scribe element.
